(19) United States
(12) Patent Application Publication
(10) Pub. No.: US 2025/0350229 A1
(43) Pub. Date: Nov. 13, 2025

(54) POWER INVERTER, MOTOR CONTROL DEVICE INCLUDING THE SAME AND METHOD OF OPERATING THE SAME

(71) Applicant: SAMSUNG ELECTRONICS CO., LTD., Suwon-si (KR)

(72) Inventors: Taehun KIM, Suwon-si (KR); Mingu KO, Suwon-si (KR); Youngcheol KIM, Suwon-si (KR); Jongseob KIM, Suwon-si (KR); Gyeongseon PARK, Suwon-si (KR); Seongjo HONG, Suwon-si (KR)

(73) Assignee: SAMSUNG ELECTRONICS CO., LTD., Suwon-si (KR)

(21) Appl. No.: 18/926,895

(22) Filed: Oct. 25, 2024

(30) Foreign Application Priority Data
May 9, 2024 (KR) 10-2024-0061467

(51) Int. Cl. H02P 27/06; B60L 3/00; B60L 15/00; B60L 53/22; H02J 7/00; H02P 29/02

(52) U.S. Cl. CPC H02P 27/06; B60L 3/003; B60L 15/007; B60L 53/22; H02J 7/0068; H02P 29/02

(57) ABSTRACT

A power inverter is provided. The power inverter includes: first, second and third legs configured to output alternating voltages having different phases. Each the first leg, the second leg, and the third leg includes: a first power metal oxide semiconductor field effect transistor (MOSFET) on a SiC substrate, and connected between a power terminal of direct current voltage and an output terminal configured to output a voltage of a corresponding phase among the first phase, the second phase and the third phase; a second power MOSFET on the SiC substrate, and connected between the output terminal and a ground terminal; and a redundancy circuit including a redundancy power transistor configured to replace the first power MOSFET based on the first power MOSFET failing and replace the second power MOSFET based on the second power MOSFET failing.

### CROSS-REFERENCE TO RELATED APPLICATION

This application claims priority to Korean Patent Application No. 10-2024-0061467, filed on May 9, 2024, in the Korean Intellectual Property Office, the disclosure of which is incorporated herein by reference in its entirety.

### BACKGROUND

The present disclosure relates to a power inverter, a motor control device including the same and a method of operating the same.

A three-phase inverter is a device that converts power into three-phase alternating current. A three-phase inverter may convert direct current power into alternating current power. A three-phase inverter may generate desired voltages and currents by controlling output waveforms. A three-phase inverter may stably supply power to connected loads by controlling power flow. Silicon carbide (SiC) metal oxide silicon field effect transistors (MOSFETs) may have lower electrical loss and may improve efficiency of power conversion system by providing a faster switching speed than a general Si MOSFET. The transistor may also operate reliably in high temperature environment and may reduce a space and weight.

### SUMMARY

One or more example embodiments provide a power inverter which may reduce costs of changing modules when module failure occurs.

According to an aspect of an example embodiment, a power inverter includes a first leg configured to output a first alternating voltage having a first phase; a second leg configured to output a second alternating voltage having a second phase different from the first phase; and a third leg configured to output a third alternating voltage having a third phase different from the first phase and the second phase. Each of the first leg, the second leg, and the third leg includes: a first power metal oxide semiconductor field effect transistor (MOSFET) on a SiC substrate, and connected between a power terminal of direct current voltage and an output terminal configured to output a voltage of a corresponding phase among the first phase, the second phase and the third phase; a second power MOSFET on the SiC substrate, and connected between the output terminal and a ground terminal; and a redundancy circuit including a redundancy power transistor configured to replace the first power MOSFET based on the first power MOSFET failing and replace the second power MOSFET based on the second power MOSFET failing.

According to another aspect of an example embodiment, a method of operating a power inverter includes performing a testing operation on a power module to identify a failed MOSFET; and repairing the failed MOSFET using a redundancy circuit of the power module based on the failed MOSFET being identified. The failed MOSFET is on a SiC substrate.

According to another aspect of an example embodiment, a motor control device includes a power inverter configured to provide three-phase voltages using a direct current voltage; and a controller configured to control the power inverter. The power inverter includes power modules configured to receive the direct current voltage and to output the three-phase voltages, respectively. Each of the power modules includes: a first power MOSFET on a SiC substrate, and connected between a power terminal of the direct current voltage and an output terminal configured to output a corresponding phase voltage among the three-phase voltages; a second power MOSFET on the SiC substrate, and connected between the output terminal and a ground terminal; and a redundancy circuit including a redundancy power transistor configured to replace the first power MOSFET based on the first power MOSFET failing and replace the second power MOSFET based on the second power MOSFET failing.

According to another aspect of an example embodiment, an electronic control system for a vehicle includes a battery configured to provide a direct current voltage; a charging circuit configured to charge the battery using an external power source; and a motor driver configured to change the direct current voltage to a three-phase alternating voltage and to drive a motor using the three-phase alternating voltage. The motor driver includes at least one power inverter. The at least one power inverter includes: at least one power transistor; and at least one redundancy power transistor configured to replace a failed power transistor of the at least one power transistor based on the failed power transistor being identified.

### BRIEF DESCRIPTION OF DRAWINGS

The and other aspects, features, and advantages in the example embodiment will be more clearly understood from the following detailed description, taken in combination with the accompanying drawings, in which:

FIG. 1 is a diagram illustrating a power inverter according to an example embodiment;

FIGS. 2A, 2B, and 2C are diagrams illustrating structures of a silicon carbide (SiC) metal oxide silicon field effect transistor (MOSFET) according to example embodiments;

FIG. 3 is a diagram illustrating a power inverter having a redundancy circuit according to an example embodiment;

FIG. 4 is a diagram illustrating bonding of a power inverter according to an example embodiment;

FIG. 5 is a diagram illustrating bonding of a power inverter according to an example embodiment;

FIG. 6 is a diagram illustrating bonding of a power inverter according to an example embodiment;

FIG. 7 is a flowchart illustrating a testing operation of a power inverter according to an example embodiment;

FIG. 8 is a flowchart illustrating a testing operation of a redundancy MOSFET according to an example embodiment;

FIG. 9 is a diagram illustrating a motor control device according to an example embodiment;

FIG. 10 is a diagram illustrating an electronic control system for a vehicle according to an example embodiment;

FIG. 11 is a diagram illustrating a motor control system according to an example embodiment;

FIG. 12 is a diagram illustrating a SiC double trench structure according to an example embodiment;

FIG. 13 is a diagram illustrating a SiC insulated-gate bipolar transistor (IGBT) structure according to an example embodiment;

FIG. 14 is a diagram illustrating a hybrid inverter system according to an example embodiment; and

FIG. 15 is a diagram illustrating a motor driving circuit according to an example embodiment.

### DETAILED DESCRIPTION

Hereinafter, example embodiments will be described with reference to the accompanying drawings. Each example embodiment provided in the following description is not excluded from being associated with one or more features of another example or another example embodiment also provided herein or not provided herein but consistent with the present disclosure. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

According to an example, embodiment, a power inverter may have an extended lifetime by applying redundancy when a power module fails. For example, the power inverter in an example embodiment may be implemented by applying a silicon carbide (SiC) metal oxide silicon field effect transistor (MOSFET) redundancy circuit in a SiC module. When an SiC MOSFET fails in a power module, the entire power module may need to be replaced. By applying a redundancy SiC MOSFET in a power module in which SiC MOSFET is applied, such as a three-phase inverter, a lifetime of the power module may be extended.

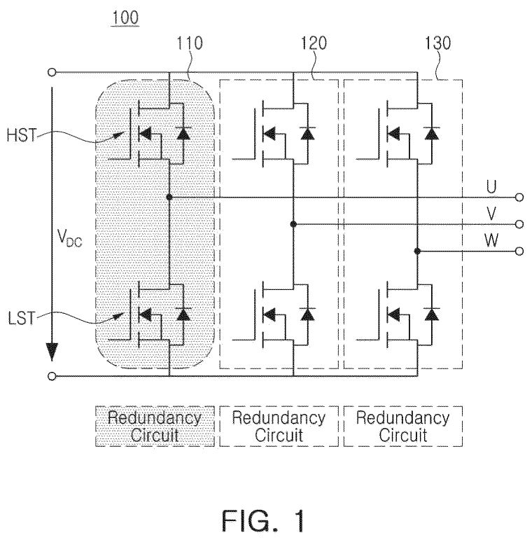

FIG. 1 is a diagram illustrating a power inverter according to an example embodiment. Referring to FIG. 1, a power inverter 100 may include legs 110, 120, and 130. The power inverter 100 may provide three-phase power by supplying three-phase currents, which for example may be used to drive a motor. For example, the first leg 110 may correspond to a first phase U (120°), the second leg 120 may correspond to a second phase V (240°), and the third leg 130 may correspond to a third phase W (360°).

Each of the legs 110, 120, and 130 may be implemented to receive a direct current (DC) voltage VDC and to output a voltage having a corresponding phase among the three-phase U, W, and W. Each of the legs 110, 120, and 130 may be connected to the DC voltage VDC and may include a pair of transistors arranged in a half-bridge configuration for converting DC voltage to AC voltage. For example, the first leg 110 may include a high-side transistor HST and a low-side transistor LST. The high-side transistor HST and the low-side transistor LST may be connected to each other in series and may be implemented to be switched on and off in a complementary manner to drive the phase load. In an example embodiment, each of the high-side transistor HST and the low-side transistor LST may be configured as a power transistor. Here, the power transistor may be implemented as a SiC MOSFET. The pair of transistors in the second leg 120 and the third leg 130 may be similarly implemented.

Also, the power inverter 100 may include redundancy circuits to replace a failed MOSFET in each of the legs 110, 120, and 130. In an example embodiment, a redundancy circuit may be activated in real time upon confirmation of failure during an inverter operation. In an example embodiment, each of the legs 110, 120, and 130 may be implemented as a power module. Each power module may include a redundancy circuit to repair a failed leg or a failed power transistor during a testing operation. That is, the redundancy circuit may include a redundant leg to replace the failed leg (i.e., may include a redundant high-side transistor HST and a redundant low-side transistor LST) or a redundant power transistor to replace the failed power transistor (i.e., may replace either the high-side transistor HST or the low-side transistor LST). In FIG. 1, for ease of description, the first leg 110 may be replaced (or repaired) by a redundancy circuit.

The power module in an example embodiment may be implemented using a SiC MOSFET and a Si integrated circuit (IC) simultaneously. Here, the Si IC may include a repair control circuit to replace the failed SiC MOSFET with a redundancy SiC MOSFET. In an example embodiment, a SiC MOSFET and a repair SiC MOSFET may be implemented in a wafer. Thereafter, the SiC MOSFET and the repair SiC MOSFET may be bonded to a substrate. In an example embodiment, the SiC MOSFETs and the repair SiC MOSFETs may be isolated from each other in series on a wafer. Here, isolation may indicate that the wafer substrate may be shared due to Ar implant, and the chip may be separated and connected by a circuit router. In an example embodiment, a redundancy circuit may be implemented in the power module. In this case, each power module may perform a repair control by bonding only the SiC MOSFET. In this regard, by including a repair control circuit in the power module, repair of the SiC MOSFETs connected by bonding may be controlled. In an example embodiment, SiC module redundancy may enable redundancy replacement after confirming failure (leakage, open, or the like) during electrical die sorting (EDS) and while operating in the field.

A power inverter may improve heat dissipation when applied to a power module such as a three-phase inverter by manufacturing a MOSFET from a SiC wafer. Also, the power inverter may perform bidirectional current control using a MOSFET and a phase change material (PCM). For example, the PCM may be encapsulated and placed on or around the surface of the MOSFET. The heat generated by the MOSFET may be conducted to the PCM, and the PCM may absorb the heat by changing its phase to reduce the temperature of the device. However, when leakage occurs in the SiC MOSFET, the general power inverter may replace the entire power module to which the SiC MOSFETs are applied.

The power inverter 100 according to an example embodiment may include a redundancy circuit in a power module using a SiC MOSFET. The power inverter 100 in an example embodiment may perform a repair operation through a redundancy circuit, such that, even when a SiC MOSFET fails in the power module, the entire power module may not need to be replaced.

Three legs 110, 120, and 130 are illustrated in FIG. 1. However, the number of legs of the power inverter in an example, and example embodiments are not limited thereto.

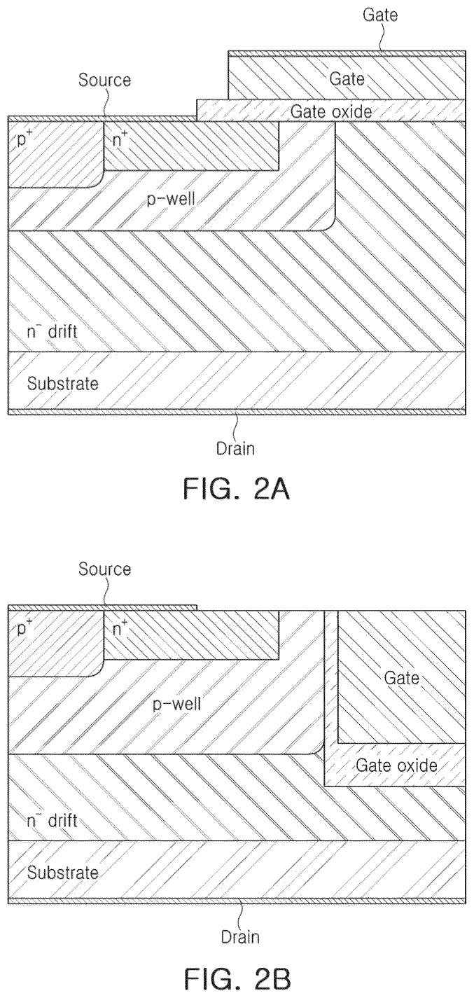

FIGS. 2A, 2B, and 2C are diagrams illustrating structures of a SiC MOSFET according to example embodiments. A SiC MOSFET may include a body diode having a P-N junction between a source and a drain. The SiC MOSFET may be implemented as a planar MOSFET as illustrated in FIG. 2A, a trench MOSFET as illustrated in FIG. 2B, or a super junction MOSFET as illustrated in FIG. 2C. The planer MOSFET illustrated in FIG. 2A may have a structure similar to a general Si MOSFET structure. This planer structure may use SiC as a substrate and may form a gate by forming an oxide film thereon. The trench MOSFET illustrated in FIG. 2B may form a gate by forming a deep trench vertically on the SiC substrate. The trench may enable efficient gate control. The trench MOSFET structure may improve high voltage intensity and may improve switching speed. The super junction MOSFET illustrated in FIG. 2C may improve high voltage intensity using a special type of P-N junction for distributing voltage.

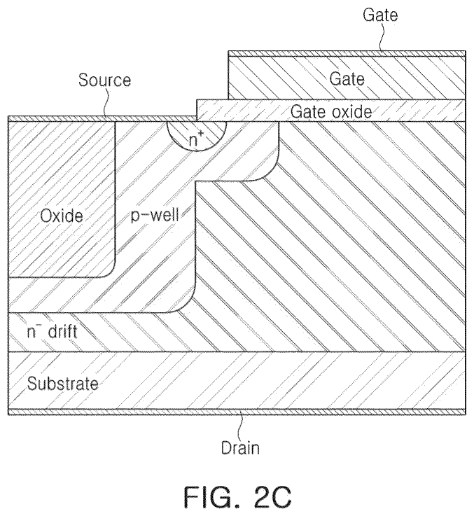

FIG. 3 is a diagram illustrating a power inverter having a redundancy circuit according to an example embodiment. Referring to FIG. 3, a power inverter 200 may include power modules 210, 220, and 230 corresponding to phases U, V, and W, respectively. Each of the power modules 210, 220, and 230 may include a redundancy circuit to replace a MOSFET that fails. For example, the power modules 210, 220, and 230 may respectively include redundancy circuits 215, 225, and 235 to repair when a MOSFET fails. Each of the power modules 210, 220, and 230 may be configured as a leg illustrated in FIG. 1. In this case, each leg may include a redundancy circuit. In an example embodiment, each of the redundancy circuits 215, 225, and 235 may include at least one MOSFET.

The power inverter 200 according to an example embodiment may use the redundancy circuits 215, 225, and 235 when a SiC MOSFET fails, such that the power module may not need to be replaced.

A power inverter according to an example embodiment may include a controller configured to drive the redundancy circuits 215, 225, and 235, that is, a controller configured to control a repair operation to replace a power transistor with a repair (or, redundancy) power transistor.

In the power inverter according to an example embodiment, the power transistor and the redundancy power transistor may be bonded to the controller in various manners.

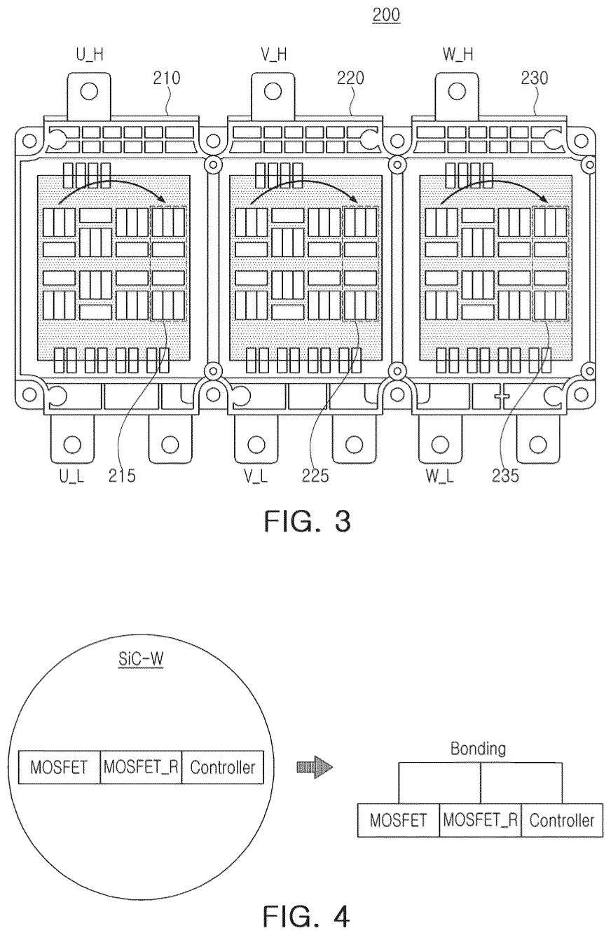

FIG. 4 is a diagram illustrating bonding of a power inverter according to an example embodiment. Referring to FIG. 4, in an example embodiment, a MOSFET, a redundancy MOSFET, and a controller may be manufactured in a wafer SiC-W. Thereafter, the power module may be manufactured by bonding the MOSFET, redundancy MOSFET MOSFET_R, and the controller to each other. The MOSFET, the MOSFET_R, and the controller may be physically and/or electrically connected to each other by wire bonding, solder bonding, or flip-chip bonding.

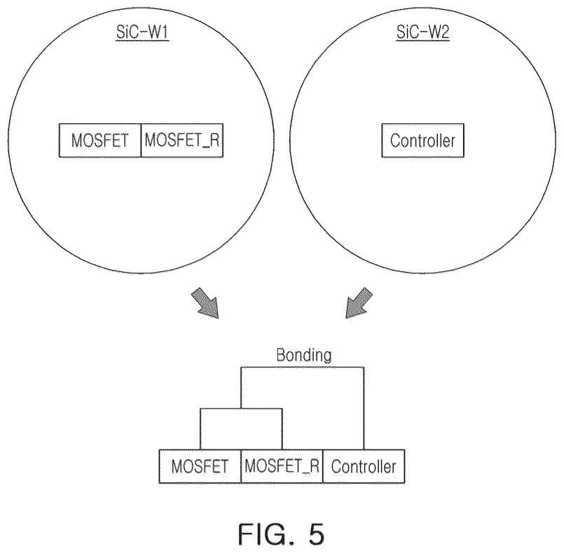

FIG. 5 is a diagram illustrating bonding of a power inverter according to an example embodiment. Referring to FIG. 5, a MOSFET and a redundancy MOSFET may be manufactured in a first wafer SiC-W1, and a controller may be manufactured in a second wafer SiC-W2. Thereafter, a power module may be manufactured by bonding the controller to the MOSFET and the redundancy MOSFET of the first wafer SiC-W1 and the second wafer SiC-W2.

The second wafer SiC-W2 illustrated in FIG. 5 may be a SiC wafer, but example embodiments are not limited thereto. The controller may also be manufactured on a Si wafer.

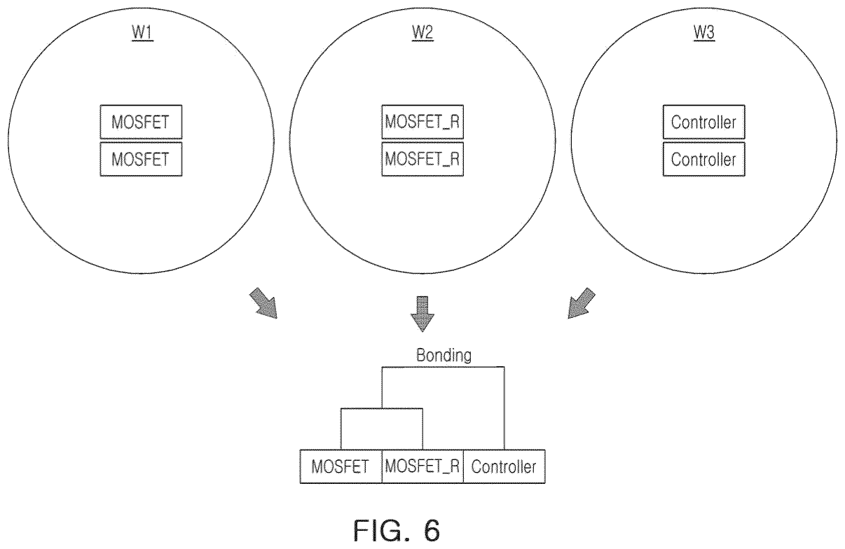

FIG. 6 is a diagram illustrating bonding of a power inverter according to an example embodiment. Referring to FIG. 6, a MOSFET may be manufactured on a first wafer W1, a redundancy MOSFET may be manufactured on a second wafer W2, and a controller may be manufactured on a third wafer W3. That is, the MOSFET, the MOSFET_R, and the controller may be individually manufactured in different wafers.

In an example embodiment, each of the first and second wafers W1 and W2 may be configured as a SiC wafer. In an example embodiment, the third wafer W3 may be configured as a Si wafer. In another example embodiment, the third wafer W3 may be configured as a SiC wafer. Thereafter, the power module may be manufactured by bonding the controller to the MOSFET of the first wafer W1, the redundancy MOSFET of the second wafer W2, and the third wafer W3.

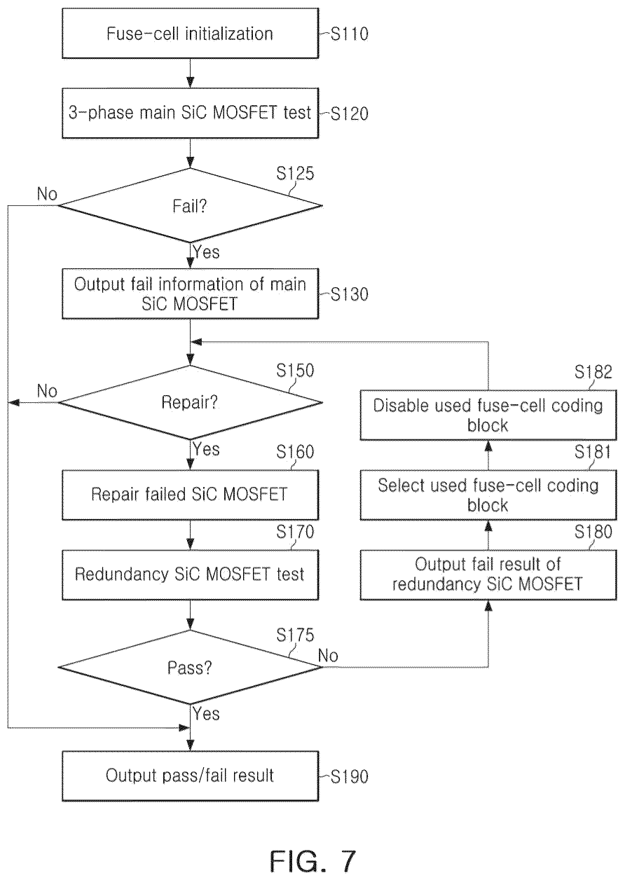

FIG. 7 is a flowchart illustrating a testing operation of a power inverter according to an example embodiment. Referring to FIG. 7, a power inverter testing operation may be performed according to an example embodiment.

A fuse-cell initialization operation may be performed (S110). Here, fuse-cell coding may indicate determining or changing a fuse to perform redundancy. That is, the repair SiC MOSFET may be electrically connected/disconnected by fuse-cell coding. A testing operation for three-phase main SiC MOSFET may be performed (S120). For example, the testing operation may include any one or any combination of a gate oxide reliability test, a threshold stability test, a body diode energization test, a short circuit resistance test, a dV/dt destruction test, a neutron immunity test, an electrostatic destruction immunity, or other similar test. Here, the testing operation may be performed by an external testing device or controller. As a result of the testing operation, it may be determined whether the three-phase main SiC MOSFET fails (S125). When the three-phase main SiC MOSFET fails, the failure information of the main SiC MOSFET may be output to an external device (test device or controller) (S130). Based on the failure information, it may be determined whether to repair the main SiC MOSFET (S150). For example, it may be determined whether the main SiC MOSFET is repairable. When the three-phase main SiC MOSFET is repairable, the failed MOSFET may be repaired by the redundancy SiC MOSFET (S160). Thereafter, a testing operation for the redundancy SiC MOSFET may be performed (S170). Thereafter, it may be determined whether the testing operation for the redundancy SiC MOSFET passes (S175). When the testing operation for the redundancy SiC MOSFET does not pass, the failure result of the redundancy SiC MOSFET may be output to an external device (S180). The used fuse-cell coding block may be selected (S181). Thereafter, the used fuse-cell coding block may be disabled (S182). Thereafter, operation S150 may be performed again using, for example, another fuse-cell coding block.

Also, when the three-phase main SiC MOSFET does not fail in operation S125, the three-phase main SiC MOSFET is not repairable in operation S150, or the testing operation for the redundancy SiC MOSFET is passed, the pass/failure result of the testing operation for the power inverter may be output to an external device.

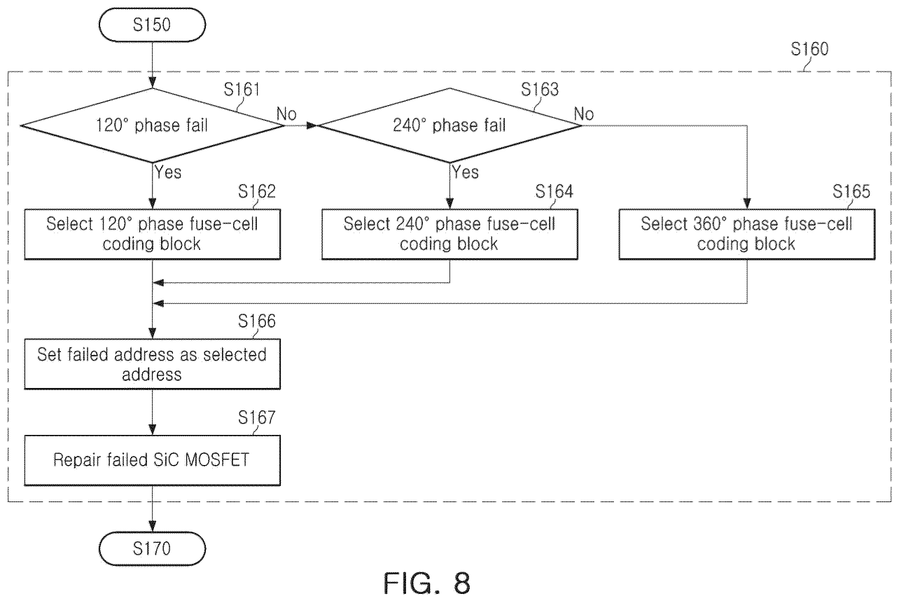

FIG. 8 is a flowchart illustrating a testing operation of a redundancy MOSFET according to an example embodiment. Referring to FIG. 8, the testing operation of the redundancy SiC MOSFET may be performed as below.

After operation S150, it may be determined whether the SiC MOSFET of first phase U (120°) fails (S161). When the SiC MOSFET of first phase U (120°) fails, the first phase U (120°) fuse-cell coding block may be selected (S162). When the SiC MOSFET in the first phase U (120°) does not fail, it may be determined whether the SiC MOSFET at the second phase V (240°) fails (S163). When the second phase V (240°) SiC MOSFET fails, the second phase V (240°) fuse-cell coding block may be selected (S164). When the SiC MOSFET of the second phase V (240°) does not fail, the third phase W (360°) fuse-cell coding block may be selected (S165).

Thereafter, the failed address may be determined as a selected address (S166). Thereafter, the failed SiC MOSFET may be repaired (S167). Thereafter, operation S170 may be performed.

The power inverter according to an example embodiment may be implemented in a motor control system.

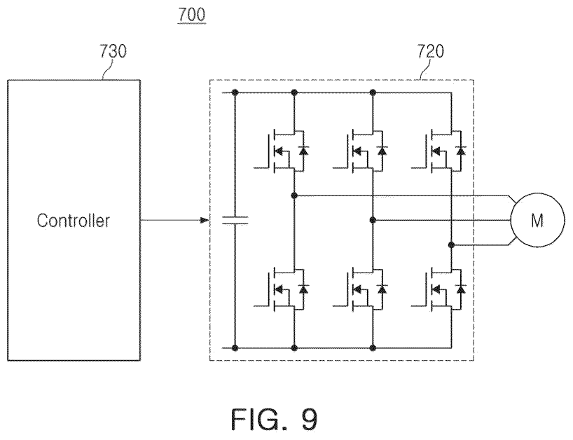

FIG. 9 is a diagram illustrating a motor control device 700 according to an example embodiment. Referring to FIG. 9, the motor control device 700 may include a power inverter 720 and a controller 730. The motor control device 700 may be further coupled to a three-phase motor M including three phases U, V, and W.

The power inverter 720 may perform a three-phase current generator function of providing three-phase power by supplying three-phase currents to drive the motor M. In an example embodiment, the power inverter 720 and the controller 730 may be disposed on the same circuit board or on separate circuit boards. Deviations in both magnitude and phase may result in loss in power and torque in the motor M. Accordingly, the motor control device 700 may monitor and control, in real time, the magnitude and phase of the currents supplied to motor M to ensure that an appropriate current balance is maintained based on a feedback control loop. Also, the power inverter 720 may be implemented by a redundancy circuit and operation thereof to repair a failed power transistor, as described in FIGS. 1 to 8.

The controller 730 may be implemented to control operations of the power inverter 720. Here, the controller 730 may be referred to as a motor controller or a motor control IC. The controller 730 may be divided into a microcontroller configured to control overall operations of the power inverter and a gate driver configured to control gate voltages provided to the power inverter 720. In an example embodiment, the controller 730 may include a motor control circuit and a gate driver circuit for controlling the switching array. In an example embodiment, the controller 730 may be monolithic such that a motor control circuit and a gate driver circuit are integrated on a single die. In another example embodiment, the motor control circuit and the gate driver circuit may be partitioned as individual ICs.

The motor control device 700 may perform a motor control function in real time. Here, the motor control function may include controlling a permanent magnet motor or an induction motor. For example, the motor control function may include sensor-less control, which does not require rotor position detection, or sensor-based control using Hall sensors or an encoder device. In this regard, the motor control device 700 may include one or more Hall sensors and an encoder device. The encoder device may include encoding circuitry.

The power inverter according to an example embodiment may be applicable to an electronic control system for a vehicle.

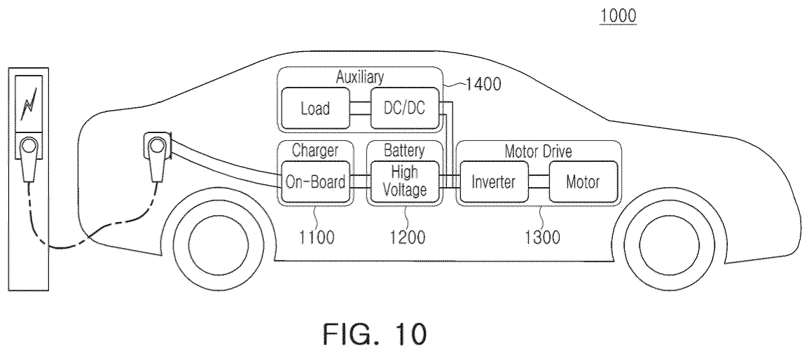

FIG. 10 is a diagram illustrating an electronic control system 1000 for a vehicle according to an example embodiment. Referring to FIG. 10, the electronic control system 1000 for a vehicle may include a charger (i.e., charging circuit) 1100, a battery 1200, a motor driver (i.e., motor driving circuit) 1300, and an auxiliary electronic device 1400.

The charger 1100 may be implemented to receive external power. The battery 1200 may be implemented to receive external power from the charger 1100 and may charge with direct current voltage (e.g., high voltage). The motor driver 1300 may be implemented to receive direct current voltage from the battery 1200, to change the direct current voltage to a three-phase alternating voltage, and to drive a motor using the three-phase alternating voltage. The motor driver 1300 may include a power inverter configured to control the motor. Here, the power inverter may include a redundancy circuit as described in FIGS. 1 to 9.

The auxiliary electronic device 1400 may include electronic devices (load) providing various services to the vehicle and a DC/DC converter configured to convert to supply direct current power required for the electronic devices. Here, the DC/DC converter may be implemented as a buck converter configured to convert a high voltage of the battery 1200 into the necessary direct current voltage.

In example embodiments, the power inverter may be applied to single mode/dual mode inverter switching.

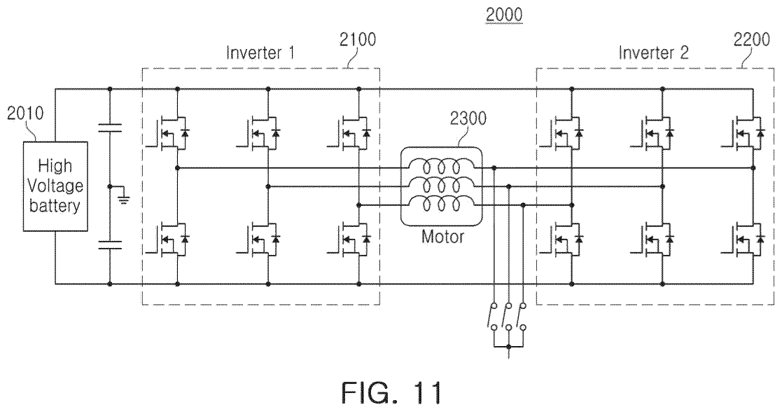

FIG. 11 is a diagram illustrating a motor control system 2000 according to an example embodiment. Referring to FIG. 11, the motor control system 2000 may include a battery 2010, a first inverter 2100, a second inverter 2200, and a motor 2300. The motor control system 2000 may change the highest efficiency point according to a driving circumstance through single inverter/dual inverter switching. In this regard, when driving in a general circumstance, the inverter may operate in single inverter mode with a first stage, and when driving at high speed, the inverter may operate in dual inverter mode with the first stage and a second stage. A 2-stage inverter may electrically optimize efficiency according to RPM. During general driving, the first inverter 2100 may operate independently, and during high output driving, the first inverter 2100 and the second inverter 2200 may operate to increase voltage utilization to increase output. Also, mode switching of a 2-stage inverter may be performed based on complex determination depending on the torque of the motor control system 2000, rounds per minute (RPM), battery voltage, degree of pressing an accelerator pedal, and battery state of charge (SoC). Each of the first inverter 2100 and the second inverter 2200 may repair a MOSFET including a redundancy circuit as described in FIGS. 1 to 9.

The example embodiment may be extended to a power transistor having various structures.

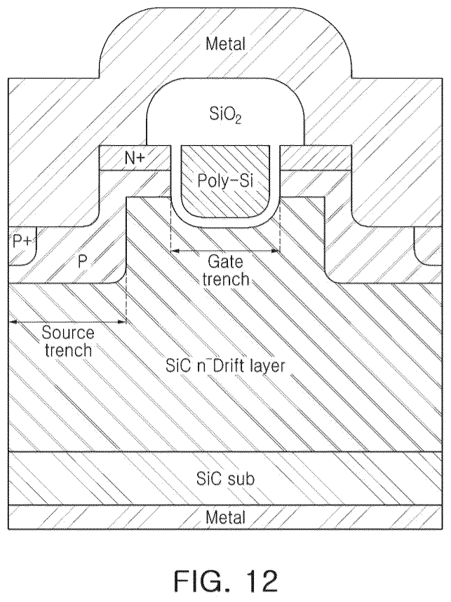

FIG. 12 is a diagram illustrating a SiC double trench structure according to an example embodiment. As illustrated in FIG. 12, the power transistor may include a gate of a trench structure and a source of a trench structure.

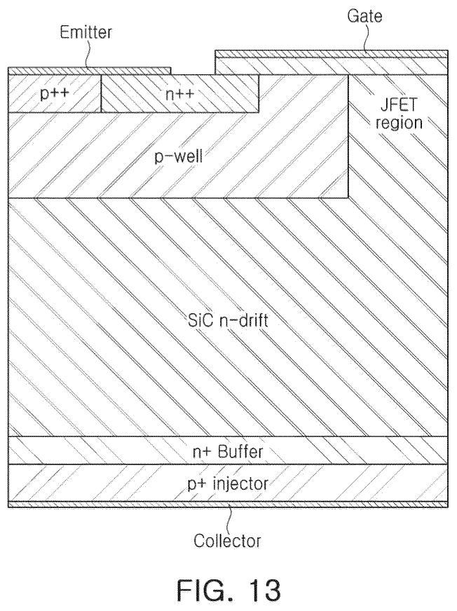

FIG. 13 is a diagram illustrating a SiC insulated-gate bipolar transistor (IGBT) structure according to an example embodiment. As illustrated in FIG. 13, the SiC IGBT may be formed by forming an IGBT on a SiC substrate. Generally, an IGBT may be mainly used for high power transmission and control. SiC may provide high thermal stability for operating stably at high temperature. Accordingly, the power transistor having a SiC IGBT structure may be advantageous in terms of high power, high temperature operation, high frequency characteristics, low power loss, long lifespan and reliability.

The power inverter according to an example embodiment may also be applied to a hybrid inverter.

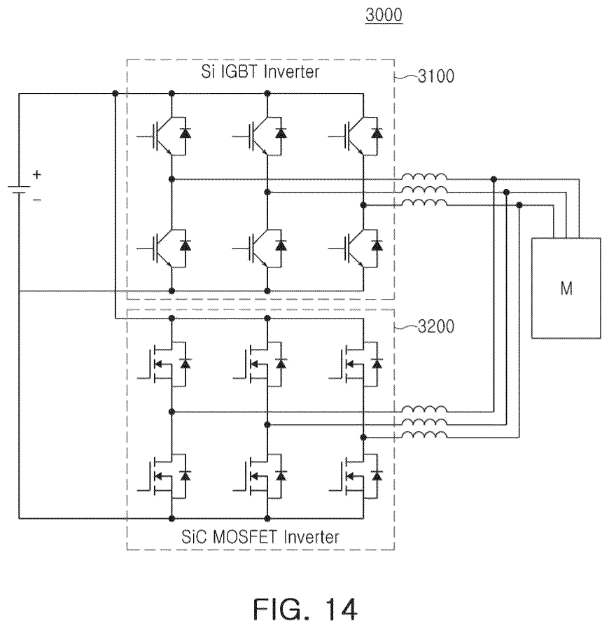

FIG. 14 is a diagram illustrating a hybrid inverter system 3000 according to an example embodiment. Referring to FIG. 14, the hybrid inverter system 3000 may include a first inverter 3100 and a second inverter 3200. The first inverter 3100 may be an inverter including Si IGBTs. The second inverter 3200 may be an inverter implemented as a SiC MOSFET. The second inverter 3200 may repair a failed SiC MOSFET by a redundancy circuit as described in FIGS. 1 to 9. Also, the failed Si IGBT of the first inverter 3100 may also be repaired by a redundancy circuit.

In example embodiments, circuits necessary for driving a motor may be implemented on a SiC substrate.

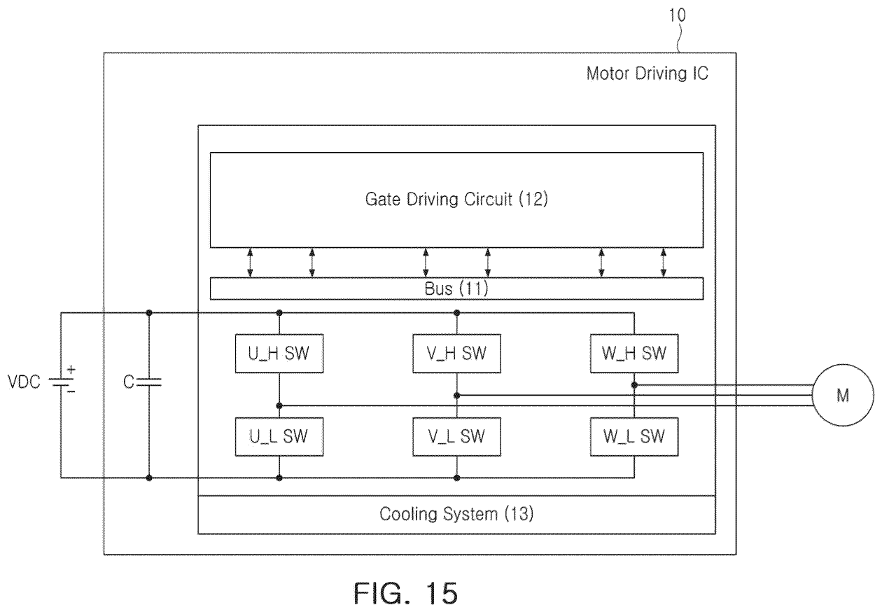

FIG. 15 is a diagram illustrating a motor driving circuit MDI according to an example embodiment. Referring to FIG. 15, the motor driving circuit MDI 10 may include a gate driving circuit 12, power switches U_H SW, U_L SW, V_H SW, V_L SW, W_H SW, and W_L SW, and a cooling system 13, connected to a bus 11.

The gate driving circuit 12 may generate driver signals for controlling each of the power switches U_H SW, U_L SW, V_H SW, V_L SW, W_H SW, and W_L SW, and may transfer the signals to the corresponding power switches U_H SW, U_L SW, V_H SW, V_L SW, W_H SW, and W_L SW through the bus 11. The gate driving circuit 12 may determine a conducting state (i.e., on state) or a blocking state (i.e., off state) for each of the power switches. The gate driving circuit 12 may receive commands including power transistor control signals from the microcontroller and may turn each power switch on or off according to the received commands and control signals. In an example embodiment, each of the power switches U_H SW, U_L SW, V_H SW, V_L SW, W_H SW, and W_L SW may be repaired by a redundancy circuit as described in FIGS. 1 to 9.

The cooling system 13 may be implemented to flow cooling liquid to power switches to dissipate heat generated in the motor control, and prevent the power switches from overheating.

The device described above may be implemented with hardware components, software components, and/or a combination of hardware components and software components. For example, the device and components described in an example embodiment may be implemented using one or more general-purpose or special-purpose computers such as a processor, a controller, an arithmetic logic unit (ALU), a digital signal processor, a microcomputer, a field programmable gate array (FPGA), and a programmable logic unit (PLU), a microprocessor, or any other device which may execute instructions and respond. A processing device may execute an operating system (OS) and one or more software applications performed on an operating system. Also, a processing device may access, store, manipulate, process and generate data in response to the execution of software. For ease of description, a single processing device may be used, but the processing device may include a plurality of processing elements or a plurality of types of processing elements. For example, a processing device may include a plurality of processors or a processor and a controller. Also, other processing configurations, such as parallel processors, may be available.

In example embodiments, a redundancy MOSFET may be applied to a SiC applied module, such as a three-phase inverter. The overshooting MOSFET connection may be changed through a controller in the SiC module. For example, an inverter may be implemented in a bonding structure to a module while the MOSFET, the redundancy MOSFET, and the controller are connected simultaneously in a wafer. In an example embodiment, an inverter may be implemented such that a MOSFET, a redundancy MOSFET and also an IC controller may be bonded to each other in a wafer in a module. In another example embodiment, the inverter may be implemented such that the MOSFET, the redundancy MOSFET, and the IC controller are bonded to each other in module as individual components.

Also, an example embodiment may be applied to a SiC MOSFET, and also to a SiC super junction structure, a SiC double trench structure, and a three-phase inverter module to which SiC IGBT is applied.

As discussed above, one or more example embodiments provide a power inverter and a method of operating the same in which a redundancy circuit in the power module is used, such that, even when a power transistor fails, a repair operation may be performed without changing the entire module.

The power inverter and a method of operating the same may reduce costs for module replacement using a redundancy circuit when module failure occurs.

While aspects of example embodiments have been illustrated and described above, it will be configured as apparent to those skilled in the art that modifications and variations may be made without departing from the scope in the example embodiment as defined by the appended claims.

1. A power inverter, comprising:
a first leg configured to output a first alternating voltage having a first phase;
a second leg configured to output a second alternating voltage having a second phase different from the first phase; and
a third leg configured to output a third alternating voltage having a third phase different from the first phase and the second phase,
wherein each of the first leg, the second leg, and the third leg comprises:
a first power metal oxide semiconductor field effect transistor (MOSFET) on a SiC substrate, and connected between a power terminal of direct current voltage and an output terminal configured to output a voltage of a corresponding phase among the first phase, the second phase and the third phase;
a second power MOSFET on the SiC substrate, and connected between the output terminal and a ground terminal; and
a redundancy circuit comprising a redundancy power transistor configured to replace the first power MOSFET based on the first power MOSFET failing and replace the second power MOSFET based on the second power MOSFET failing.

2. The power inverter of claim 1, further comprising a first power module comprising the first leg, a second power module comprising the second leg, and a third power module comprising the third leg,
wherein each of the first power module, the second power module and the third power module is provided on the SiC substrate.

3. The power inverter of claim 1, wherein the redundancy power transistor comprises a redundancy MOSFET on the SiC substrate.

4. The power inverter of claim 3, further comprising a controller configured to control a fuse-cell coding block to replace a failed MOSFET with the redundancy MOSFET.

5. The power inverter of claim 4, wherein the MOSFET, the redundancy MOSFET, and the controller are provided on a wafer and connected to each other.

6. The power inverter of claim 4, wherein the MOSFET and the redundancy MOSFET are provided on a first wafer,
wherein the controller is provided on a second wafer different from the first wafer,
wherein the MOSFET and the redundancy MOSFET are module-bonded to each other, and
wherein the controller is bonded to the MOSFET.

7. The power inverter of claim 4,
wherein each of the MOSFET, the redundancy MOSFET, and the controller are provided on different wafers, and
wherein the MOSFET, the redundancy MOSFET, and the controller are module-bonded to each other.

8. The power inverter of claim 4, wherein the controller is provided on a Si wafer.

9. The power inverter of claim 1, wherein the redundancy circuit is configured to activate upon confirmation of failure while an inverter operates.

10. The power inverter of claim 1, wherein the redundancy circuit is configured to activate based on failure information of a failed power transistor during a wafer testing operation.

11-15. (canceled)

16. A motor control device, comprising:
a power inverter configured to provide three-phase voltages using a direct current voltage; and
a controller configured to control the power inverter,
wherein the power inverter comprises power modules configured to receive the direct current voltage and to output the three-phase voltages, respectively, and
wherein each of the power modules comprises:
a first power metal oxide semiconductor field effect transistor (MOSFET) on a SiC substrate, and connected between a power terminal of the direct current voltage and an output terminal configured to output a corresponding phase voltage among the three-phase voltages;
a second power MOSFET on the SiC substrate, and connected between the output terminal and a ground terminal; and
a redundancy circuit comprising a redundancy power transistor configured to replace the first power MOSFET based on the first power MOSFET failing and replace the second power MOSFET based on the second power MOSFET failing.

17. The motor control device of claim 16, wherein the controller and the power inverter are provided on the SiC substrate.

18. The motor control device of claim 16, wherein the redundancy power transistor is comprises a SiC MOSFET.

19. The motor control device of claim 16, wherein the controller is further configured to control a failed power transistor to be replaced using the redundancy power transistor by controlling a fuse-cell coding block.

20. The motor control device of claim 19, further comprising:
a first module comprising the first power MOSFET and the second power MOSFET;
a second module comprising the redundancy power transistor; and
a third module comprising the controller,
wherein the first module, the second module, and the third module are module-bonded to the SiC substrate.

21. An electronic control system for a vehicle, the electronic control system comprising:
a battery configured to provide a direct current voltage;
a charging circuit configured to charge the battery using an external power source; and
a motor driver configured to change the direct current voltage to a three-phase alternating voltage and to drive a motor using the three-phase alternating voltage,
wherein the motor driver comprises at least one power inverter, and
wherein the at least one power inverter comprises:
at least one power transistor; and
at least one redundancy power transistor configured to replace a failed power transistor of the at least one power transistor based on the failed power transistor being identified.

22. The electronic control system for a vehicle of claim 21, wherein each of the at least one power transistor and the at least one redundancy power transistor comprises a SiC metal oxide silicon field effect transistor (MOSFET), a SiC super junction structure transistor, a SiC double trench structure transistor, or an insulated gate bipolar transistor (SiC IGBT).

23. The electronic control system for a vehicle of claim 21, wherein the at least one power inverter comprises:
a first inverter; and
a second inverter.

24. (canceled)

25. The electronic control system for a vehicle of claim 21, wherein the motor driver further comprises a gate driving circuit configured to control the at least one power inverter, and
wherein the gate driving circuit and the at least one power inverter are implemented on a SiC substrate.

26-27. (canceled)

28. The electronic control system for a vehicle of claim 21, wherein the motor driver further comprises a gate driving circuit configured to control whether to use the at least one redundancy power transistor based on failure information of a wafer.

29-30. (canceled)
